(19) United States
(12) Patent Application Publication
(10) Pub. No.: US 2026/0181884 A1
(43) Pub. Date: Jun. 25, 2026

(54) BACKSIDE ANTI-FUSES

(71) Applicant: Taiwan Semiconductor Manufacturing Company, Ltd., Hsinchu (TW)

(72) Inventor: Meng-Sheng Chang, New Taipei City (TW)

(73) Assignee: Taiwan Semiconductor Manufacturing Company, Ltd., Hsinchu (TW)

(21) Appl. No.: 19/170,973

(22) Filed: Apr. 4, 2025

Related U.S. Application Data
(60) Provisional application No. 63/737,112, filed on Dec. 20, 2024.

(51) Int. Cl. H10B 20/25

(52) U.S. Cl. CPC H10B 20/25

(57) ABSTRACT

A semiconductor device includes an active region on a frontside of the semiconductor. The active region includes an anti-fuse control cell including a plurality of first transistors. The semiconductor device includes a frontside metallization layer coupled with the plurality of first transistors. The semiconductor device includes a one-time-programmable circuit on a backside of the semiconductor device. The one-time-programmable circuit includes a second transistor coupled with a programing wordline (WLP) line of the anti-fuse control cell. The one-time-programmable circuit includes a third transistor coupled with a read wordline (WLR) line of the anti-fuse control cell. The semiconductor device includes a backside metallization layer coupled with the second and third transistor.

### CROSS-REFERENCE TO RELATED APPLICATION

This application claims priority to and the benefit of U.S. Provisional Application Number 63/737,112, filed Dec. 20, 2024, which is incorporated herein by reference in its entirety for all purposes.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductor layers of material over a substrate, and patterning the various material layers using lithography to form circuit components and elements thereon. As the semiconductor industry has progressed into nanometer technology process nodes in pursuit of higher device density, interconnect density has limited overall density of active components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example semiconductor device including an anti-fuse circuit, in accordance with some embodiments.

FIG. 2 illustrates an example schematic of a memory cell of an anti-fuse, in accordance with some embodiments.

FIG. 3 illustrates another example schematic of a memory cell of an anti-fuse circuit, in accordance with some embodiments.

FIG. 4 illustrates an example cross sectional view of a semiconductor device including a two-transistor (2T) anti-fuse circuit, in accordance with some embodiments.

FIG. 5 illustrates an example cross sectional view of a semiconductor device including a three-transistor (3T) anti-fuse circuit, in accordance with some embodiments.

FIG. 6 illustrates a further example schematic of a memory cell of an anti-fuse circuit, in accordance with some embodiments.

FIG. 7 illustrates an example cross sectional view of a semiconductor device including a symmetrical three-transistor (3T) anti-fuse circuit, in accordance with some embodiments.

FIG. 8 illustrates another example cross sectional view of a semiconductor device including a two-transistor (2T) anti-fuse circuit, in accordance with some embodiments.

FIG. 9 illustrates another example cross sectional view of a semiconductor device including a three-transistor (3T) anti-fuse circuit, in accordance with some embodiments.

FIG. 10 illustrates another example cross sectional view of a semiconductor device including a symmetrical three-transistor (3T) anti-fuse circuit, in accordance with some embodiments.

FIG. 11 illustrates an example cross sectional view of backside vias (VB) of a semiconductor device, in accordance with some embodiments.

FIG. 12 illustrates an example cross sectional view of backside vias (VB) and feed-though-vias (FTV) of a semiconductor device, in accordance with some embodiments.

FIG. 13 illustrates an example layout view of a semiconductor device, in accordance with some embodiments.

FIG. 14 illustrates another example layout view of a semiconductor device, in accordance with some embodiments.

FIG. 15 illustrates a schematic view of a programming decoder of a semiconductor device, in accordance with some embodiments.

FIG. 16 illustrates a cross-sectional view of components of the programming decoder of a semiconductor device, in accordance with some embodiments.

FIG. 17 illustrates a flow diagram for a method of semiconductor device fabrication, in accordance with some embodiments.

FIG. 18 illustrates a cross-sectional view of a backside via (VB), in accordance with some embodiments.

FIG. 19 illustrates a cross-sectional view of a feed-through-via (FTV), in accordance with some embodiments.

FIG. 20 illustrates a flow diagram for a method of data encoding, in accordance with some embodiments.

FIG. 21 illustrates a flow diagram for a method of accessing one-time programmable data, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Generally, one-time programmable devices can be implemented as fuses or anti-fuses. Fuses can refer to or include a conductive element configured to break an electrical connection in a circuit, such that the one-time programming can result in an open circuit which can be sensed to resolve to a digital value. An anti-fuse can refer to or include a dielectric element configured to breakdown to form a breakdown resistor. For example, the dielectric element can include a gate oxide of a transistor which, when broken down by a programming voltage applied via a programing word line (WLP), forms a gate breakdown resistor. The gate breakdown resistor may be coupled with a read wordline (WLR) configrued to recive a sense voltage and a bit line configurd to read out a state of the bit cell. For exmaple, reading out the state of the cell can determine whether the circuit is open, as in the case of a non-broken down dielectic or closed, as in the case of a broken down dielectric of a breakdown resistor.

According to the present disclosure, an active area can be disposed on a frontside of a semiconductor device. For example, the active area can include transistors, diodes, or other active components. The active circuitry can include a control cell for a bit cell of a (one-time) programmable memory, such as an anti-fuse control cell for an antifuse bit cell. The use of the backside of the semiconductor device can densify the device, relative to an implementation including the antifuse bit cells on a same surface as the active circuitry. The active circuitry can further include a processor or memory configured to access information encoded in the bit cells on the backside of the semiconductor device. The accessed information can be provided to such circuits incident to their operation. For example, the accessed information can include firmware, security keys, or other data which is accessed incident to device operation.

Various via structures can extend between the frontside and backside of the semiconductor device to provide programming or read access, of the bit cells, by the active circuitry. For example, backside via structures can extend between one of a source or drain of a transistor in the active area. Although providing backside via structures to a same node for each of the source and drain would generally short the transistor and thus impair its operation, an inactive region laterally spaced from the active area (e.g., a p-tap region or other tap structure) can include backside via structures in each of a source/drain region of a dummy transistor. Moreover, other conductive structures, such as feed-through via structures may electrically couple control cells on the frontside of the semiconductor device with bit cells on the backside of the semiconductor device. These feed-through via structures may be disposed in either or both of the active or inactive regions.

Various of the via structures can be combined to form parallel paths between the frontside and backside of the semiconductor device. For example, some semiconductor devices can include backside via structures coupled with a source in an active region, backside via structures coupled with a source and drain of an inactive region, or feed-through via structures coupled in either or both of the active regions and the inactive regions. A through substrate resistance can be managed according to a number of through-substrate vias (and their parallel paths). In some embodiments, the via structures can couple with or through a backside power rail between frontside and backside transistors, backside metallization layers formed over the bit cells, or frontside metallization layers formed over the control cells. In some embodiments, some through substrate via structures (e.g., backside via structures) may couple with an MD layer or directly with a source/drain region.

Various gate breakdown resistors can be included to increase a read current. For example, first and second gate breakdown resistors can be formed from coupling with WLP lines Substitute Specification-Clean for parallel paths, and to further provide redundancy. Further, various read resistors can be provided to provide parallel paths of read current passed through the one or more gate breakdown resistors. For example, in a 3T configuration, a WLP line can be coupled with a gate terminal of a breakdown transistor/resistor, while two other transistors can provide parallel, redundant, or other diverse paths for a read current.

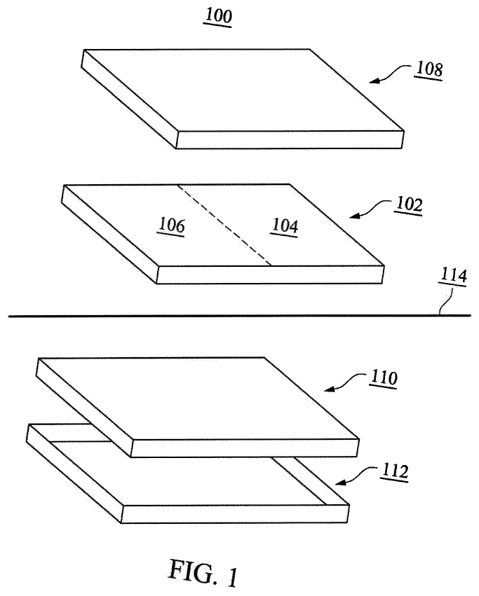

FIG. 1 illustrates a block diagram of an example semiconductor device 100 including an anti-fuse circuit, in accordance with some embodiments. The semiconductor device 100 can include various frontside circuits 102. The frontside circuits 102 can include one or more active regions 104, as may include processors, memory devices, clocks, and control cells for anti-fuse or other bit cells. For exmaple, the active regions 104 can include a processor or other circuit configured to execute instructions based on a value of information stored on a backside of the semiconductor device 100 (e.g., firmware, encryption keys, or so forth). The frontside circuits 102 can include one or more inactive regions 106, as may include guard rings, isolation cells, dummy cells, fill cells, test structures, or so forth. For example, the frontside circuits 102 can include one or more cells having dummy transistors (sometimes referred to as space cells or spare gates) which may be used to form via structures between the frontside circuits 102 and a backside of the semiconductor device 100 (e.g., a backside metallization layer 112).

The frontside metallization layers 108 (as may include an MD, M0, M1, M2 layer, and so forth) can interconnect various circuitry of the frontside circuits 102, and may further couple with through-substrate via structures coupled with the backside of the semiconductor device 100 (e.g., a backside metallization layer 112). Backside circuits 110 can include bit cells for a programmable memory (e.g., a fuse or anti-fuse), as may be coupled with control cells of the frontside circuits 102. For example, the frontside circuits 102 can program, and subsequently read the programmable bit cells. An active region 104 on the frontside of the semiconductor device 100 can laterally overlap with the backside circuits 110 (e.g., a one-time programmable circuit thereof), as may reduce a lateral run of an interconnect, to reduce resistance of lines between the frontside and backside. Such reduced resistance can increase a read speed or decrease a read error rate.

The backside metallization layers 112 (as may include an MD, BM0, BM1, BM2 layer, and so forth) can interconnect various backside components of the semiconductor device 100 and further couple with through-substrate via structures coupled with the frontside of the semiconductor device 100.

The semiconductor device 100 can include a backside power rail 114. For example, the backside power rail 114 can be formed on a backside of a substrate, such that thin film or other transistors of the backside circuits 110 may be formed over the backside power rail 114. The through-substrate via structures can couple with, or include portions of the backside power rail 114, or may be formed according to a same layer or process used to form the backside power rail 114.

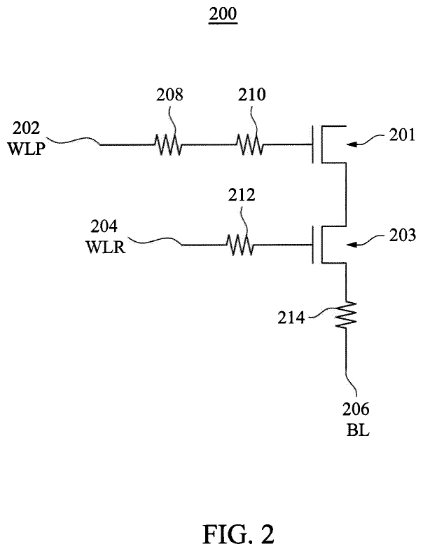

FIG. 2 illustrates an example schematic of a memory cell 200 of an anti-fuse, in accordance with some embodiments. More particularly, the memory cell 200 is provided as an unprogrammed memory cell including a bit cell coupled with lines for a control cell by through-substrate via structures. These lines include a WLP line 202, WLR line 204, and bit line 206 coupled with the control cell for the depicted bit cell of the anti-fuse, as is coupled with the frontside circuit 102.

A connection from a gate of a first transistor 201 of the bit cell with the WLP line 202 includes a first resistance 208 related to connections between the frontside circuits 102 and a through-substrate via structure. For example, such a resistance 208 can include any resistance of a frontside metallization layer 108. The first transistor 201 is sometimes referred to as a sacrificial or breakdown transistor. According to the depicted illustrative example, such a resistance 208 is omitted for the WLR line 204 and the BL 206. Such an example can correspond to an example wherein the WLR line 204 and the BL 206 do not connect to the backside of the semiconductor device 100 through the frontside metallization layers 108 (or where such a resistance is lumped into other depicted resistances). Such an example should not be construed as limiting. Some WLR line 204 or BL 206 connect via various of the frontside metallization layers 108, just as some WLP lines 202 omit such connections. A connection with the WLP line 202 includes a second resistance 210 related to connections between (and inclusive of) the through-substrate via structures or backside metallization layers 112.

Prior to programming, these first and second resistances 208, 210 may not substantially impact circuit operation, since a gate current of a backside transistor generally exhibits negligible gate currents (e.g., for a thin-film FET, such as a transistor having an indium-gallium-zinc-oxide (IGZO). However, once a gate voltage exceeds a breakdown voltage for the gate oxide (or another dielectric), the first transistor 201 can function as a resistor (sometimes also described as a short circuit). Such a resistor may be referred to as a breakdown resistor, or more specifically, as a gate breakdown resistor where the broken-down gate oxide forms a resistive conduction path between the source and drain. Similarly, a resistance 212 of the WLR line 204 coupled with a gate of a second transistor 203, or a third resistance 214 for the bit line 206, can include a resistive component from any of the frontside metallization layers 108, through-substrate vias, or backside metallization layers 112. However, due to the low gate currents, the values of these resistances may impact circuit operation less than other resistances, such as a bit line resistance 214, an on-state resistance of the second transistor 203, or other resistance along a read current path when the second transistor 203 is engaged to conduct a sense current between its source/drain regions.

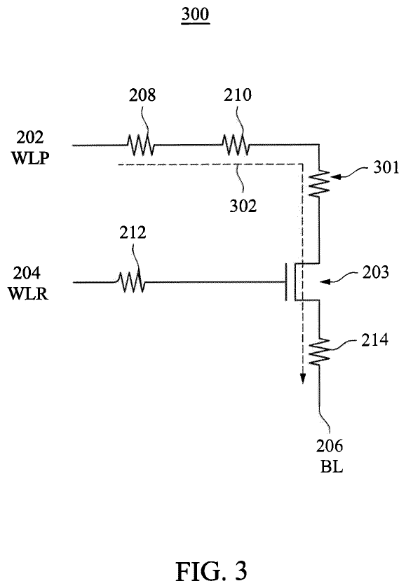

FIG. 3 illustrates another example schematic of a memory cell 300 of an anti-fuse circuit, in accordance with some embodiments. More particularly, the memory cell 200 is provided as a programmed memory cell. The WLP line 202, WLR line 204, and bit line 206 are shown as coupled with a control cell for the anti-fuse, depicted in FIG. 2. However, the first transistor 201 of FIG. 2 is depicted in a post-programming, broken down state (as a breakdown resistor 301). Such a circuit is sometimes referred to as a one-time-programmable circuit. Accordingly, a current 302 received at the bit line 206 will be a function of a voltage provided to the WLR lines 204, along with the first resistance 208, second resistance 210, a further resistance of the breakdown resistor 301, and the third resistance 214. Accordingly, a read speed or accuracy may be improved by increasing the current, as may be achieved according to the selection of materials or geometry of the various resistances, including a number of parallel paths than may be provided for all or a portion of a path of the sense current 302 for the state of the bit cell.

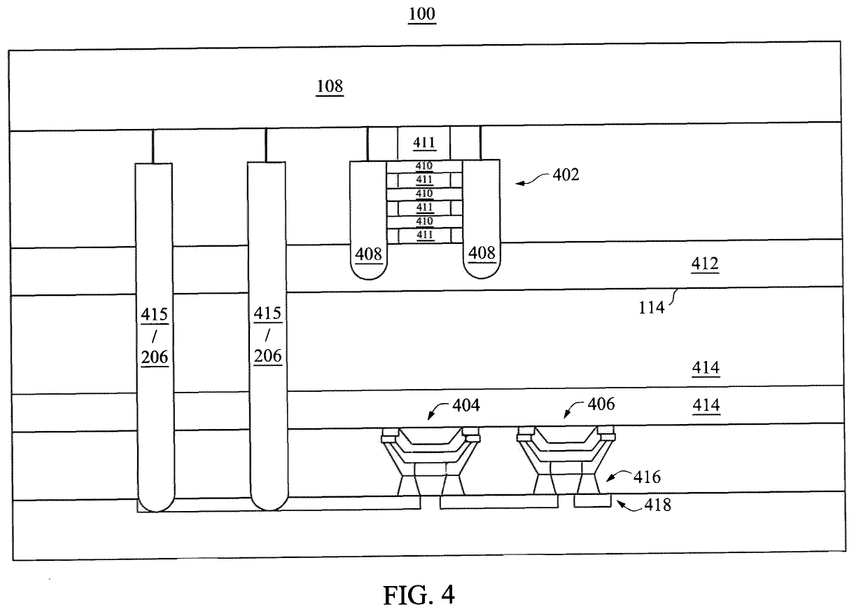

FIG. 4 illustrates an example cross sectional view of a semiconductor device 100 including a two-transistor (2T) anti-fuse circuit, in accordance with some embodiments. The frontside circuits 102 can include various transistors, including a depicted example of a nanosheet transistor, and more particularly, as a gate all around field effect transistor (GAAFET) 402. According to various embodiments, the frontside circuit 102 can further include, or the GAAFET 402 can be substituted for a finFET, planar FET, or other active components. The frontside circuit 102 (e.g., the GAAFET 402) can couple with various devices on a backside of the device, such as the depicted bit cell including a first transistor 404 and second transistor 406 (as may correspond to the first transistor 201 and second transistor 203 of FIG. 2).

Although a single instance of a frontside transistor 402 is depicted to aid with the clarity of the present figure, the circuit will generally include numerous transistors, including numerous transistors of a control cell for the anti-fuse bit cell, as well as further transistors of circuits configured to process information received from various examples of the bit cell. Similarly, although a single instance of a backside bit cell is depicted to aid with the clarity of the present figure, any number of bit cells can be provided. For example, one bit cell can be provided to provide one bit of information, or millions of bit cells can be provided to provide megabits of information. Some bit cells can be allocated for test structure function, parity checks, or further uses.

Referring more particularly to the GAAFET 402, the GAAFET 402 include various semiconductive channels 410 extending between first and second source/drain regions 408. The semiconductor channels are gated by a gate structure 411. The gate structure 411 can, in turn, couple with a frontside metallization layer 108, as may include an MD layer and various further metallization layers (e.g., an M0, M1, M2 layer, and so forth). Stacked layers of nanosheets of the semiconductive channels 410 extend over a substrate 412. The substrate 412 can make up a substantial vertical portion (e.g., a majority) of the semiconductor device 100. For example, the substrate can include a silicon or other semiconductive substrate, a glass substrate, or other substrate.

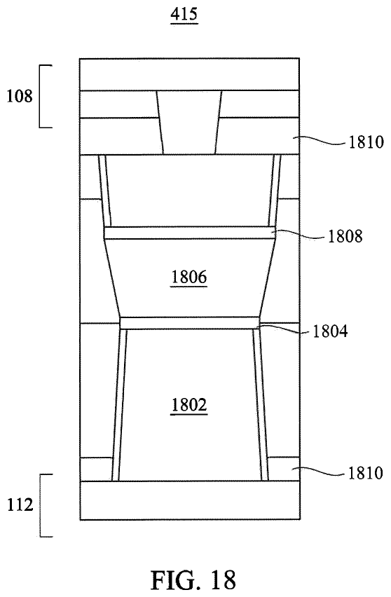

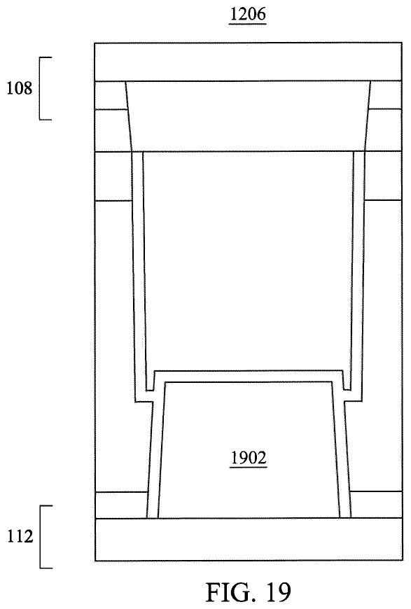

A backside power rail 114 is formed over the backside of the substrate 412, opposite from the GAAFET 402. Further layers may be formed over the backside power rail 114, as may include oxide 414 layers or other ILD. The first transistor 404 and second transistor 406 of the backside are formed over the oxide layers 414 or other ILD. These first and second transistors 404, 406 can correspond to the first and second transistors 201, 203 of FIG. 2, in some embodiments. The backside metallization layers 112 couple with and interconnect the first transistor 404 with the second transistor 406. The backside metallization layers 112 further couple the first transistor 404 and the second transistor 406 with through-substrate interconnects, such as the depicted backside via structures (VB) 415. A more detailed illustrative example of a VB 415 is provided henceforth, at FIG. 18. The VB 415 (or other via structures) can couple with the source/drain regions of the GAAFET 402 via a frontside metallization layer 108 formed thereover, or otherwise. In some embodiments, the VB 415 may be substituted for or supplemented by another through substrate via structure, such as an FTV, an illustrative example of which is provided henceforth, at FIG. 19.

As depicted, the backside metallization layers 112 includes first contacts 416 coupling the first transistor 404 and second transistor 406 with a BM0 layer 418 of the backside metallization layers 112. Although not depicted, the backside metallization layers 112 can include additional layers, such as a BM1, BM2, or further constituent layers. The depicted through via structures can provide a low resistance bit line 206, or other aspects of the anti-fuse cell, such as a WLP line 202, WLR line 204, or so forth.

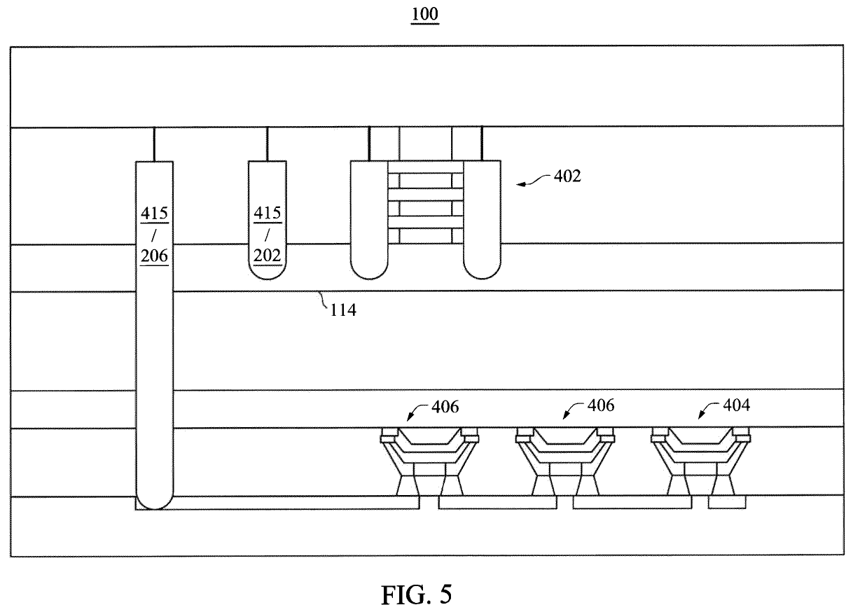

FIG. 5 illustrates an example cross sectional view of a semiconductor device 100 including a three-transistor (3T) anti-fuse circuit, in accordance with some embodiments. The depicted example of the 3T circuit can include a single transistor 404 coupled with a WLP line 202 (as depicted for the first transistor 201 of FIG. 2) and two transistors 406 coupled with a WLR line 204 (e.g., corresponding to the second transistor 203 of FIG. 2). Conversely, some 3T circuits include two (breakdown) transistors having a gate coupled with a WLP line 204 and a single transistor having a gate coupled with a WLR line 404. The two transistors 406 depicted as coupled with the WLR line 204 may be configured to provide parallel currents to the bit line 206, which may be implemented according to two through-substrate via structure (as depicted in FIG. 4), one through-substrate via structure, or another number of through-substrate via structures. The control cell on the frontside of the semiconductor device 100 can be configured to couple with two bit lines 206 separately (for redundancy), or to a single node carrying the currents of both bit lines 206 (e.g., to increase read margin or read speed). The depicted VB 415 (or other through substrate via structures) can couple with the backside power rail 114 for further routing. Further signals can be similarly routed (e.g., from the source/drain regions 408). For example, a WLP line 202 or WLR line 204 may be so connected, and may couple with the backside transistors 404, 406 via further through-substrate via structures (not depicted). For example, these further through-substrate via structures can be disposed laterally away from the through-substrate via structures of the bit line 206, since any increased resistance may not substantially impair circuit operation for relatively low gate currents of backside transistor 404, 406 (e.g., an IGZO FET).

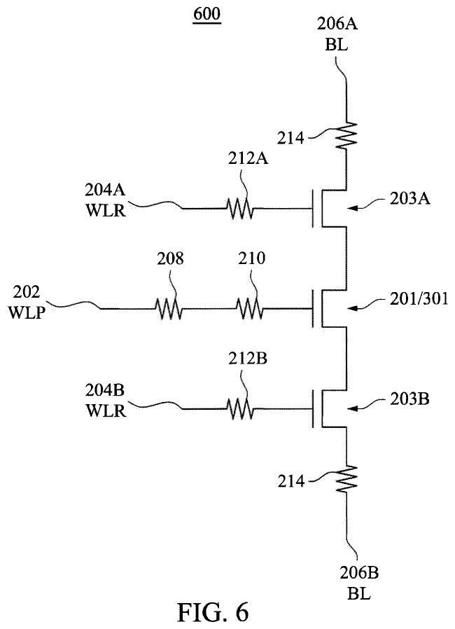

FIG. 6 illustrates a further example schematic of a memory cell 600 of an anti-fuse circuit, in accordance with some embodiments. As depicted with regard to FIG. 2, the WLP line 202 couples with an anti-fuse memory device, depicted as a first transistor 201. When exposed to sufficient voltage (sometimes referred to as a programming voltage), a gate oxide or other dielectric of the first transistor 201 can break down to form a breakdown resistor 301 (an example of which is depicted in FIG. 3).

A source/drain of the first transistor 201 is coupled with a second transistor 203A, and the other source/drain of the first transistor 201 is coupled with another second transistor 203B. Respective gates of the second transistors 203A, 203B are coupled with respective WLR lines 204A, 204B. The electrical connections can include resistances 212A, 212B of the WLR lines 204A, 204B. However, a gate current of the second transistors 203A, 203B can be relatively low, especially when implemented as FETs, so as to mitigate any operational impact of this resistance. Source/drain regions of the second transistors 203A, 203B further couple with a bit line 206. For example, first and second bit lines 206A, 206B couple with a control cell on the front side of the semiconductor device 100.

In some embodiment, the bit lines 206A, 206B couple with one another at the backside metallization layers 112. In some embodiment, the bit lines 206A, 206B couple with one another at the backside power rail 114. In some embodiment, the bit lines 206A, 206B couple with one another at the frontside metallization layers 108. In some embodiments, the bit lines 206A, 206B logically couple with the control cell separately from one another, so as to provide logical redundancy. However, such an approach may reduce a nominal read speed, due to the lower current passed through the separated bit lines 206A, 206B. Accordingly, in some embodiments, the bit lines 206A, 206B form parallel paths between the first transistor 201 (or a breakdown resistor 301) and the control cell. Such a parallel path may refer to a parallel path as observed from the breakdown resistor 301, such that one of the respective parallel paths extends from a first terminal of the breakdown resistor 301, and another second parallel path extends from, a second terminal of the breakdown resistor, as is depicted in the present figure. However, such a geometry should not be construed as limiting. For example, in some embodiments, multiple second transistors 203 can couple with a same source/drain of the first transistor 201, so that the multiple bit lines 206 couple with a same terminal of the breakdown resistor 301 after programming. The current carrying paths of such an embodiment may also be referred to as parallel paths.

Although FIG. 6 depicts two bit-lines 206 coupled with two second transistors 203, further embodiments can include additional second transistors 203, such as a three, four, or five such transistors in a 4T, 5T, or 6T cell. Moreover, some embodiments, can include multiple first transistors 201, as may be programmed. For example, additional first transistor 201 may be provided for redundancy purposes, or to increased read currents. In some embodiments, the control cell is configured to discriminate between multiple current levels to resolve a state of a cell to differing logical values (e.g., a muti-bit anti-fuse bit cell).

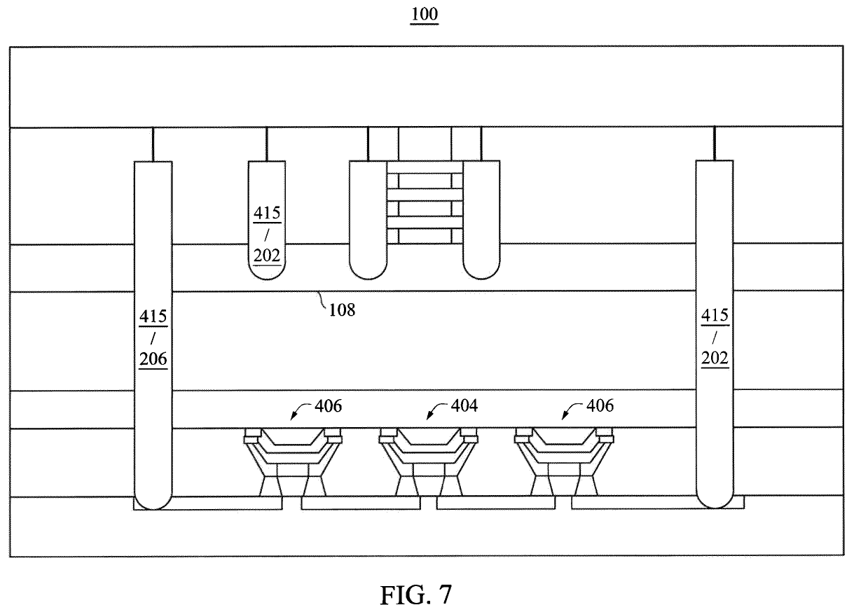

FIG. 7 illustrates an example cross sectional view of a semiconductor device 100 including a symmetrical three-transistor (3T) anti-fuse circuit, in accordance with some embodiments. The symmetrical 3T anti-fuse circuit can include a first transistor 404 having a first source/drain region coupled with a second transistor 406 and a second source/drain region coupled with another second transistor 406. That is, the present depiction can correspond to the memory cell 600 directed according to the schematic of FIG. 6. A source/drain of each of the second transistors 406 is coupled with a separate bit line 206 which couple with one-another at the frontside metallization layers 108. In some cases, the bit lines 206 can couple with one another at the backside metallization layers 112 or the backside power rail 114. Accordingly, equalization currents can flow between the separate bit lines 206, where a resistance of the VB 415, or other portions of the anti-fuse memory cell vary from one another.

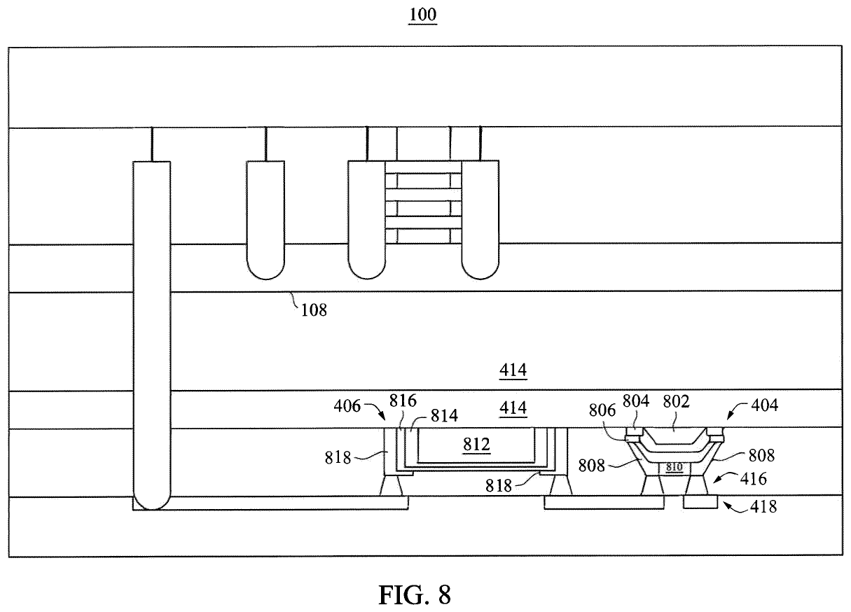

FIG. 8 illustrates another example cross sectional view of a semiconductor device 100 including a two-transistor (2T) anti-fuse circuit, in accordance with some embodiments. The 2T circuits includes transistors of different types. For example, the first transistor 404 may be referred to as a 2D transistor, and the second transistor 406 may be referred to as a 3D transistor. These examples should not be construed as limiting. For example, some implementations can include other transistor types (or other anti-fuse devices, as may include a two-terminal anti-fuse bit cell, such as a programmable metallization layer, via anti-fuse, or so forth).

Referring more particularly to the illustrative example of the first transistor 404, the first transistor 404 includes a gate structure 802. The gate structure 802 may be formed over one or more oxide layers 414 formed over the backside power rail 114. For example, the oxide layers 414 can include conductive lines and via structures coupled with other backside metallization layers 112. Accordingly, the backside transistors (e.g., 404, 406) may be referred to as formed in the backside metallization layers 112, and having a gate coupled with the backside metallization layers (e.g., to the WLP line 202). The gate structure 802 can be formed according to a deposition of a conductive gate material (e.g., Titanium Nitride, TiN), coupled with the WLP line 202. The gate layer can be formed according to additive or subtractive patterning. For example, a gate layer can be formed over the oxide layers 414 and patterned to form the depicted gate structure 802, as well as gates for any further anti-fuse bit-cells or other backside transistors as may implement various further functionality.

A gate oxide 804 can be formed over the gate structure 802. For example, the gate oxide 804 can be include a high-k dielectric such as hafnium dioxide (HfO₂) conformally formed over the oxide layer 414 and the gate structure 802. The gate oxide 804 can be formed for use in an anti-fuse, such as by forming the gate oxide 804 as a thin film which can be broken down by a programming voltage of the control cell. The gate oxide 804 can be deposited according to various techniques, such as additive or subtractive patterning, or according to a deposition process which is selective to the gate structure 802. A channel 806 (e.g., a semiconductive channel 806) can be formed over the gate oxide 804. For example, the channel 806 can include indium gallium zinc oxide (IGZO). The channel 806 can be formed according to various techniques, such as additive or subtractive patterning, or according to a deposition process which is selective to the gate oxide 804.

Source/drain regions 808 can be formed over, or otherwise in contact with, the channel 806. In some implementations, the source/drain regions 808 are formed as a contiguous layer and patterned to separate a drain from a source. In some embodiments, the source and the drain are formed separately. In some embodiments, the source/drain regions 808 can include a same material as the gate structure 802, such as TiN. An ILD 810 can separate the source from the drain. The ILD 810 can include a same material as other oxide layers 414 (e.g., silicon dioxide), or can include another material. Contacts 416 and conductive lines of a backside metallization layer 112 can be formed over or otherwise in contact with the source/drain regions 808. For example, the contacts and BMO layer can be formed according to single or double damascene processes, as may be repeated to form further layers of the backside metallization layers 112.

Referring more particularly to the illustrative example of the second transistor 406, the second transistor 406 can be formed differently from the first transistor 404. Such differences can result in lower on-state resistance, higher breakdown voltages, or so forth. In some embodiments, the second transistor 406 can share one or more materials with the first transistor 404. For example, a gate structure 812 or source/drain region 818 of the second transistor 406 can include TiN, a gate oxide 814 can include HfO₂, and a semiconductive channel 806 can include IGZO. In some implementaions, respective portions of the two transistors can be formed according to a same operation or suboperation. For exmaple, at least a portion of the gate structrures 802, 812, gate oxides 804, 814, channels 806, 816, or source/drain regions 808, 818 can be deposited or patterned according to a same operation. In some embodiments, different or intervening operations can be performed, such as to insert spaced layers or provide mask layers over one of the first transistor 404 or second transistor 406, but not the other of the first transistor 404 or second transistor 406.

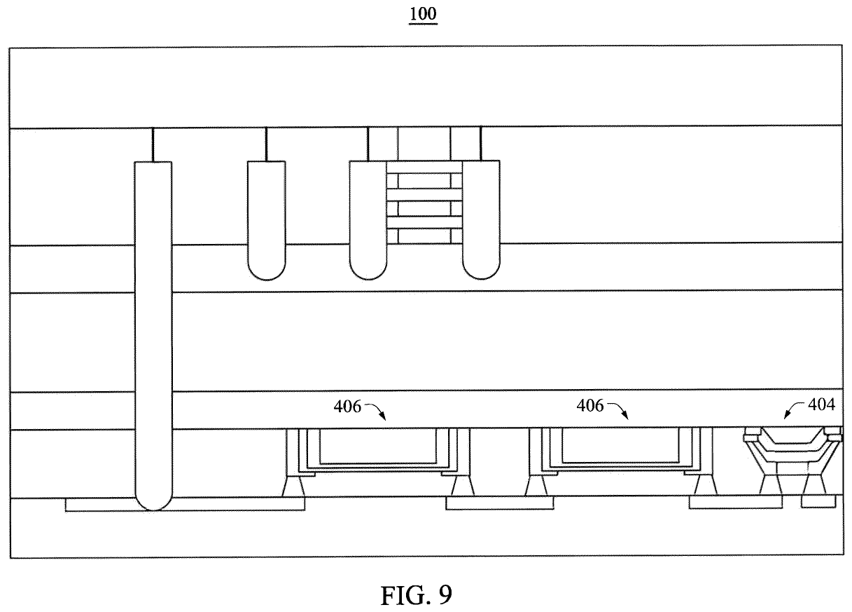

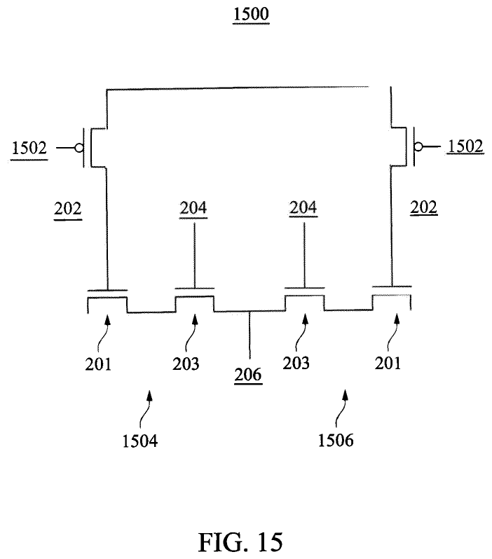

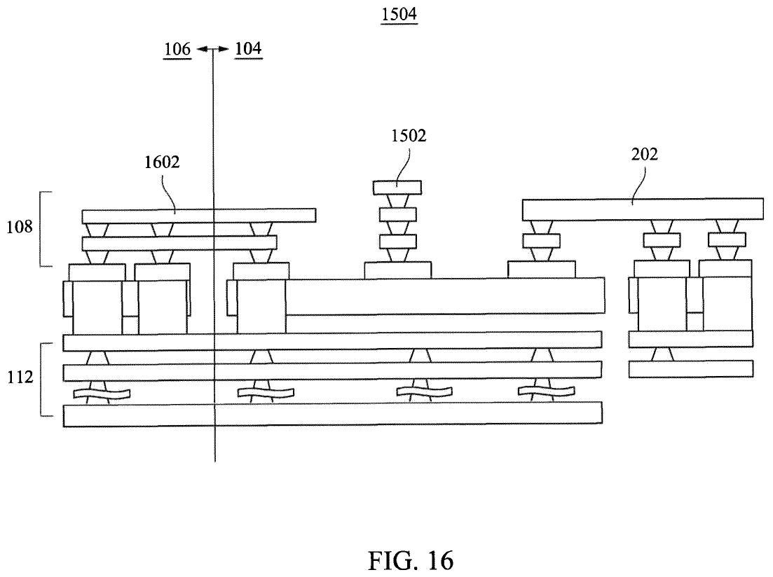

FIG. 9 illustrates another example cross sectional view of a semiconductor device 100 including a three-transistor (3T) anti-fuse circuit, in accordance with some embodiments. The depicted bit cell on the backside of the semiconductor device 100 includes a first transistor 404 of the first type, as may be configured for dielectric breakdown (e.g., to form a breakdown resistor 301). For example, the first transistor can couple with a WLP line 202, as may be implemented according to the programming circuit of FIGS. 15-16. Second transistors 406 are depicted as the second type, as may provide increased read currents.

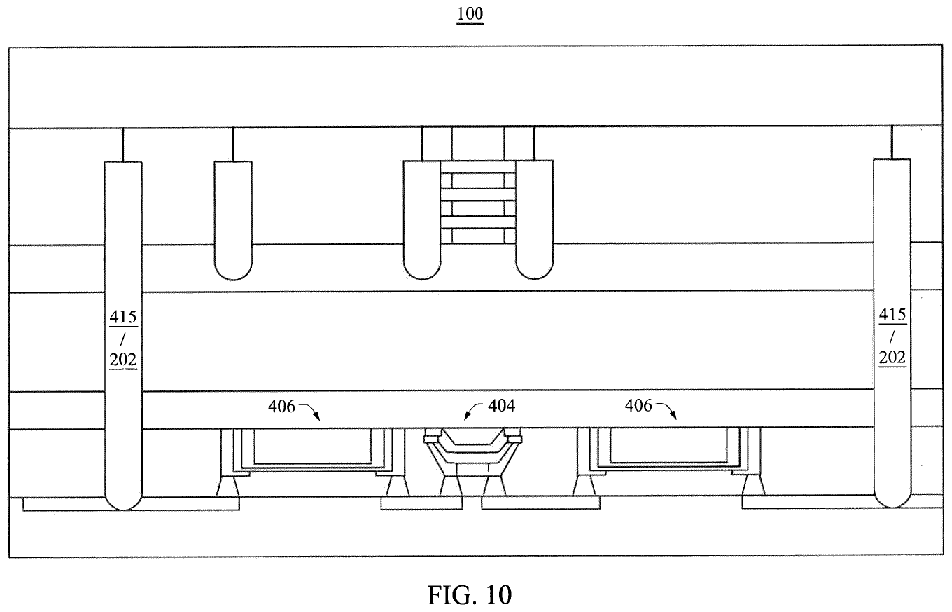

FIG. 10 illustrates another example cross sectional view of a semiconductor device 100 including a symmetrical three-transistor (3T) anti-fuse circuit, in accordance with some embodiments. As depicted with regard to FIG. 7, the second transistors 406 can provide respective parallel current paths to provide a return current provided based on a state of the first transistor 404 (e.g., whether the first transistor 404 is broken-down or not).

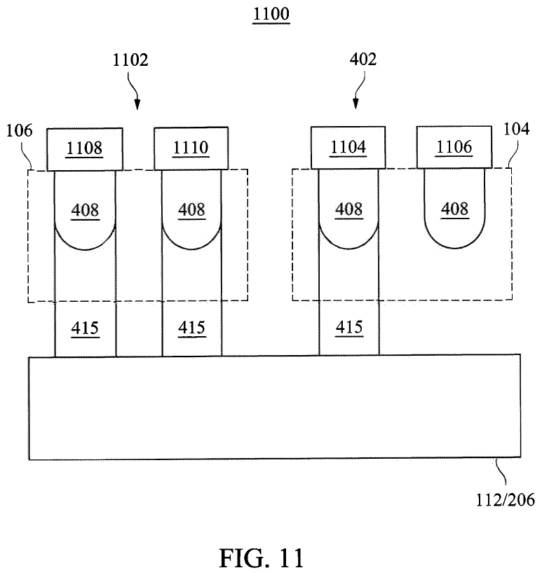

FIG. 11 illustrates an example cross sectional view 1100 of backside vias (VB) of a semiconductor device 100, in accordance with some embodiments. The view includes an active region 104 and an inactive region 106, depicted as adjacent to aid in the legibility of the figures, but which need not be adjacent. For example, laterally offset or vertically stacked regions can be electrically connected to one another using the frontside metallization layers 108 or other interconnect structure.

Within the active region 104, VB 415 can connect with the back metallization layer 112. However, only one of a source region or drain region 408 is coupled, so as to prevent shorting the source/drain regions 408 of the first transistor 402. A single transistor 402 is shown, as previously, with regard to FIGS. 4-5, 7-8, and 9-10. However, the control cell can include numerous transistors, various of which can couple with the VB 415 for the bit line 206 (as long as such selection does not short circuit or otherwise interfere with the operation of the control circuit). Conversely, a dummy transistor 1102 can include a VB 415 coupled with each of the source/drain regions 408, since no interference with a circuit will generally result. The source/drain regions 408 of the dummy transistor 1102 are so named for commonality with the first transistor 402, and do not necessarily include any particular structure, dopants, material, etc. As for the transistors 402 of the active region 104, various dummy transistors 1102 can be coupled to one another to provide further parallel VB 415 to lower overall bit line 206 resistance.

The VB 415 can, as depicted, couple with an MD contact. For example, a VB 415 is shown as coupled with a first MD contact 1104 of the first transistor 402, and not to a second MD contact 1106, to avoid shorting the first transistor 402. Conversely, respective VBs 415 are shown as coupled with each of a first MD contact 1108 and second MD contact 1110 of the dummy transistor 1102 of the inactive region 106. In some embodiments, the VB 415 can couple directly with the source/drain regions 408, rather than through the MD contacts. For example, the source/drain regions 408 can be configured to electrically couple with the VB 415 (e.g., may be heavily doped).

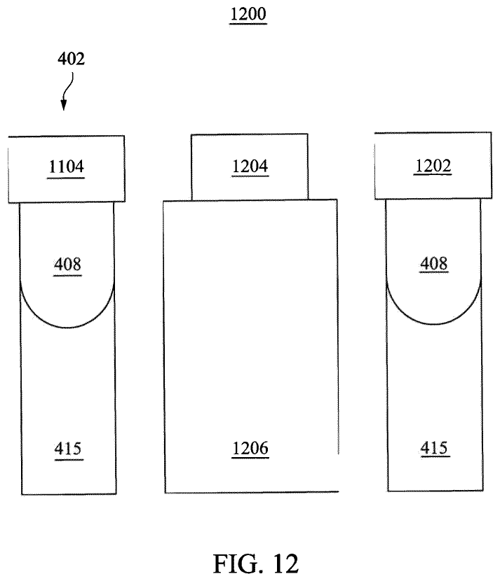

FIG. 12 illustrates an example cross sectional view 1200 of backside vias (VB) 415 and feed-though-vias (FTV) 1206 of a semiconductor device 100, in accordance with some embodiments. For example, the depicted view can be provided according to a cut plane which is perpendicular to a cut plane of FIG. 11. More particularly, the source region 408 of the first transistor 402 is depicted as laterally spaced from a further transistor of the active region 104 having a source region 408 coupled with a further MD contact 1202. Further depicted, shown laterally between the first transistor 402 and the further transistor, is a feed-through via (FTV) 1206 is depicted as coupled with another MD contact 1204. The MD contact 1204 can provide a lower resistance path than the VB 415, according to some embodiments.

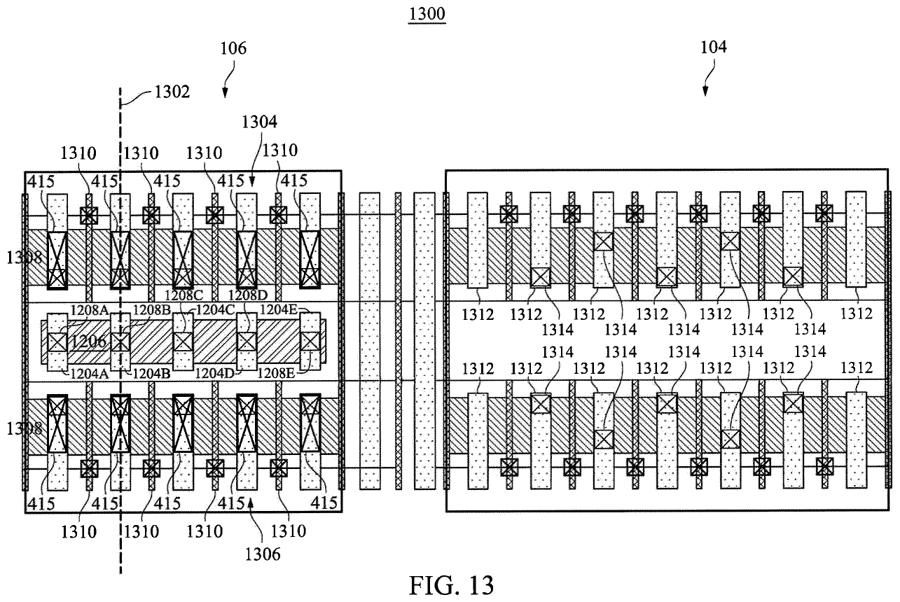

FIG. 13 illustrates an example layout 1300 of a semiconductor device 100, in accordance with some embodiments. The example layout 1300 depicts a top view of the cross-sectional view 1200 of FIG. 12 (e.g., along cutline 1302). The FTV 1206 is coupled with various MD contacts 1204 (depicted as contacts 1204A, 1204B, 1204C, 1204D, and 1204E). The FTV 1206 can couple with the MD contacts 1204 by an intermediate structure such as a depicted VD structure 1208 (e.g., depicted as VD structures 1208A, 1208B, 1208C, 1208D, 1208E). In some embodiments, the FTV 1206 can couple with additional or fewer MD contacts 1204 using additional or fewer VD structures 1208 (e.g., a single MD contact 1204 VD structure pair).

As is depicted, the FTV 1206 is disposed in an inactive region 106 between source regions 408 of first and second dummy transistors. Referring further to the dummy transistors, a first row 1304 and second row 1306 include respective oxide diffusion areas 1308. The oxide diffusion areas each include numerous source/drain regions 408 disposed across a poly gate 1310, or position therefor. Each of the source/drain regions 408 can include a VB 415 (depicted as coupled with a VD structure, VDR structure, or other conductive element). The VB 415 (or the FTV 1206) can couple the frontside of the semiconductor device 100 with a backside of the semiconductor device 100. For example, the VB 415 can carry a WLP line 202, WLR line 204, bit line 206, power rail, signal, clock, or other signals between the respective surfaces of the semiconductor device 100. Some of the VB 415 or FTV 1206 can be connected to one another, through the frontside metallization layers 108, backside metallization layers 112, or so forth.

According to the example layout 1300, the active region 104 includes various MD structures 1312 coupled with a frontside metallization layer 108 (e.g., an MO layer) by another structure, such as a VD structure 1314.

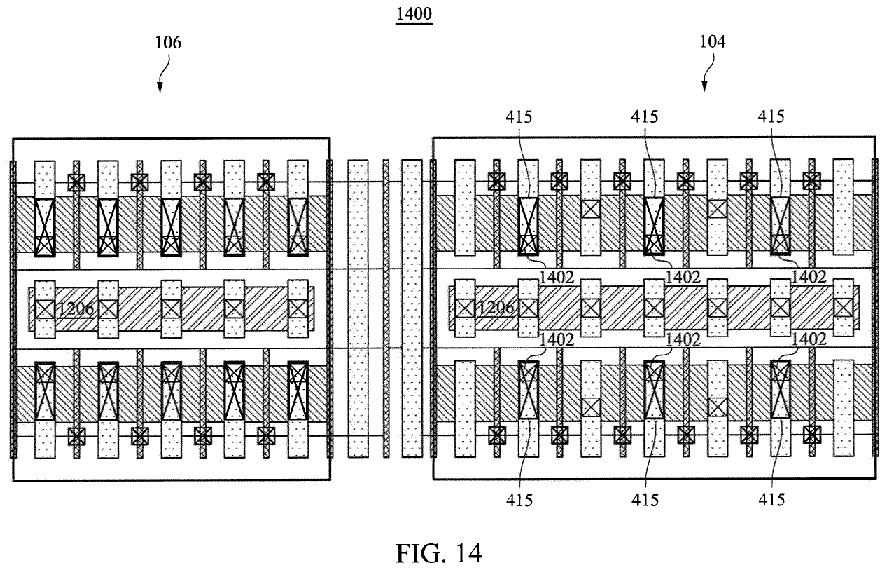

FIG. 14 illustrates another example layout 1400 of a semiconductor device 100, in accordance with some embodiments. The inactive region 106 is depicted similarly to the example layout 1400 of FIG. 13. However, additional VB 415 are depicted in various transistors of the active region 104 (and are coupled to a VD structures 1402). For example, VB 415 are depicted as coupled with various source regions 408 and omitted from drain regions 408. Further, another FTV via structure 1206 is depicted in the active region 104.

FIG. 15 illustrates a schematic view of a programming decoder 1500 of a semiconductor device 100, in accordance with some embodiments. The programming decoder 1500 can receive an input corresponding to an anti-fuse bit cell, to couple a programming voltage with a gate of the bit cell. The programming decoder 1500 can couple with a voltage generator to convey a programming voltage to one or more anti-fuses (e.g., transistors). For example, the programming voltage can cause a dielectric breakdown of a gate oxide or other dielectric of a transistor to form a breakdown resistor 301 (e.g., the breakdown resistor 301 of FIG. 3). According to a selection of some bit cells, and non-selection of others, information can be encoded. For example, selected bit cells can be broken down from the application of the programming voltage. Accordingly, a bit line current received through a breakdown resistor 301 of such a cell can resolve to a logical one or zero, wherein a reduced current (e.g., near-zero current) received from an intact first transistor 201 can resolve to the other of the logical one or zero. Such a current can be gated according to a read signal applied to a second transistor 203 (e.g., according to a voltage applied to a WLR line 204). For example, an actuation of a first control selection line 1502, CTO, can apply a programming voltage to program a first bit cell 1504, while an actuation of a second control selection line 1502, CT1, can apply a programming voltage to program a second bit cell 1506.

Although a two bit cell decoder 1500 is depicted, such operations can be repeated across various bit cells to encode additional bits of information. For example, many kilobits, megabits, gigabits, (or so forth) of information can be encoded via one or more programming decoders 1500. As is further depicted, a bit line 206 can be shared amongst multiple bit cells having separately gated WLR lines 204.

FIG. 16 illustrates a cross-sectional view of components of the programming decoder 1500 of a semiconductor device 100, in accordance with some embodiments. For clarity of illustration, aspects of CT1 1502 are omitted to depict an illustrative example of a first bit cell 1504 is greater detail. CT0 1502 is depicted as distributed by a frontside metallization layer 108, and more particularly, to an M2 layer coupled to a PO through an M1 and M0 layer (although various further signal routings are contemplated). Frontside transistors can receive the CTO signal 1502 and apply a programming signal to a gate of a first transistor 201 (e.g., may implement a decoder 1500 to form breakdown resistors 301 of a substrate backside).

As is depicted, the programming voltage, VPP 1602 can be coupled with a WLP line 202 coupled with a backside of the semiconductor device 100 (e.g., a backside metallization layer 112). More particularly, the WLP line 202 (as well as other connections, such as bit lines 206) can couple with the backside according to one or more VB 415 or one or more FTV 1206. Some of the VB 415 or FTV 1206 can be disposed in an active region 104 (e.g., a same active region 104 including a control cell for a coupled bit cell 1504, 1506). Some of the VB 415 or FTV 1206 can be disposed in an inactive region 106.

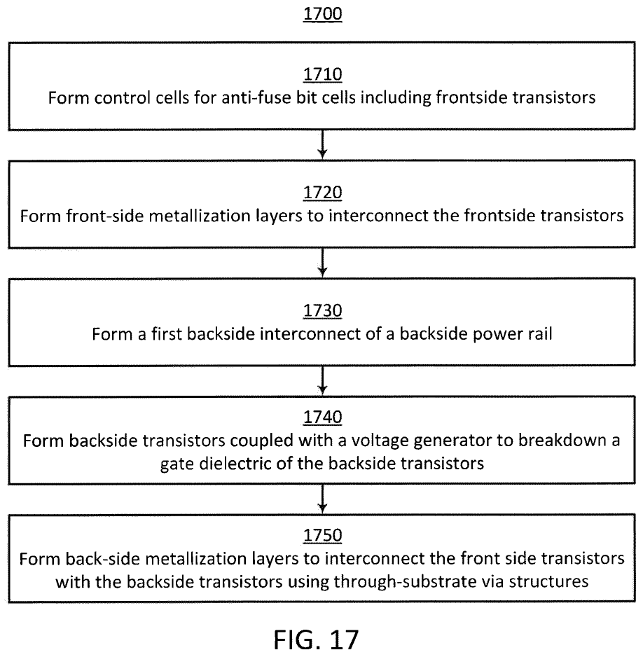

FIG. 17 illustrates a flow diagram for a method 1700 of semiconductor device 100 fabrication, in accordance with some embodiments. Some operations may only be described briefly herein. However, one skilled in the art will understand that the disclosed operations may be performed in conjunction with other disclosed methods disclosed herein, or generally known in the art. Further, the order of the disclosed operations is not intended to be limiting. Certain operations may be performed in a different sequence, and still further operations may be sequenced with appropriate modifications thereto. The operations provided herein are not intended to limit the present disclosure. For example, operations or suboperations can be added, substituted, omitted, or otherwise modified.

At operation 1710, the method 1700 includes forming frontside transistors on a front side of a substrate 412. The frontside transistors (e.g., the first transistor 402) can form control cells for a bit cell (e.g., bit cells 1504, 1506). In addition to these control cells, the front side transistors can include transistors of various logic devices, clock propagation networks, data or memory busses, input/output terminals, and other components of functionality as may be implemented using an active surface of a semiconductor device 100. The transistors can be formed according to various techniques, as may be used to form various transistor types. For example, as is depicted in any of FIGS. 4-5, 7-10, the transistors can be formed as GAAFETs, or as other 2D or 3D transistor types (e.g., finFETs, planar transistors, etc.). In some embodiments, the frontside can include multiple layers of stacked transistors, or combinations of semiconductor dies. The various transistors (along with diodes, passive devices, or other circuity) can be formed in one or more active regions 104. For example, the various active regions 104 can correspond to distinct design cells.

At operation 1720, the method 1700 includes routing interconnects over the front side of the substrate 412 (e.g., to form front side metallization layers 108). The interconnects can be formed from conductive elements disposed within an ILD. For example, single or double damascene processes can form alternating layers of via structures and lateral lines of an M0, M1, M2 layer, and so forth. The routed interconnects can form connections between devices of the active surface, as may form circuits configured to retrieve data from memory, execute arithmetic operations, store data, or perform other computational functions.

At operation 1730, the method 1700 includes forming first backside interconnects on the backside of the substrate 412. For example, the first backside interconnect can be formed as a backside power rail 114 on a backside of the substrate 412 (e.g., in contact with the substrate 412 or one or more intervening layers). In some cases, prior to executing operation 1730, a wafer or other substrate can be flipped and thinned (e.g., according to a chemical mechanical polishing or grinding process CMP/G). Such thinning can reduce a vertical dimension of the substrate, as may reduce a resistance of through-substrate vias (according to a reduction in length), and further aid their formation (e.g., according to a tapered profile of the through-substrate vias). The CMP/G or other planarization process can aid in the formation of the backside power rail 114. Operation 1730, like other aspects of the current disclosure, can be omitted, modified, or substituted. Accordingly, in some aspects of the present disclosure, through substrate via structures may couple between the frontside metallization layers 108 and the backside metallization layers 112 without coupled with or passing through a portion of the backside power rail 114.

At operation 1740, the method 1700 includes forming transistors (e.g., transistors 201, 203) on a backside of the substrate 412. The transistors 201, 203 can include thin or thick film transistors, such as the illustrative example of the transistors depicted throughout the present disclosure (e.g., can include IGZO transistors). Although some examples of anti-fuse bit cells are provided, the backside transistors should not be construed as limited to transistors to implement anti-fuse bit cells. For example, backside transistors can further include volatile memory cells, one-time-programmable fuses, test structures, logic devices, etc.

At operation 1750, the method 1700 includes forming second backside interconnects over the back side of the substrate 412. The second backside interconnects may be referred to or include a backside metallization layer 112. For example, the backside metallization layer 112 can couple various of the frontside transistors with various of the backside transistors (e.g., to implement WLP lines 202, WLR lines 204, bit lines 206, or other interconnects).

FIG. 18 illustrates a cross-sectional view of a backside via structure (VB) 415, in accordance with some embodiments. The VB 415 includes a backside via 1802 coupled with a backside metallization layer 112. The backside via 1802 couples with a semiconductive portion 1806 of the VB 415 at a first silicide junction 1804. For example, the semiconductive portion 1806 can be the substrate itself (e.g., a silicon substrate) or may be otherwise formed (e.g., epitaxially grown). Such a region is sometimes referred to as an epitaxial region. Although the semiconductive portion 1806 can be doped or otherwise formed to lower a resistivity, relative to intrinsic silicon, the semiconductive portion 1806 (and the silicide junctions 1804) can exhibit greater resistance than other portions of the VB 415 (e.g., metal portions).

The semiconductive portion 1806 further couples with an MD structure at a second silicide junction 1808. For example, the MD structure can include a source or drain MD contact 1104, 1106 of an active region 104, or a source or drain MD contact 1108, 1110 of an inactive region 106. Silicide junctions 1804, 1808 can be formed using a same metal as a metal region (or any of various metal regions) such as the backside via 1802 or the MD structure, or can be formed from another metal couplable therewith. The MD structure can further couple with various layers of a front side metallization layer 108 according to a VD structure, VDR structure, or other intermediate conductive structure. The VB 415 can extend through various intervening barrier layers 1810, such as a Silicon-Nitride (SiN) to electrically or chemically separate a front side metallization layer 108 or backside metallization layer 112 from other portions of the semiconductor device 100. The VB 415 can couple with or include a conductive line of a backside power rail 114, in some embodiments.

FIG. 19 illustrates a cross-sectional view of a feed-through-via structure (FTV) 1206, in accordance with some embodiments. As is depicted, the FTV 1206 is a metal FTV 1206, lacking a semiconductive portion 1806 (and silicide junctions 1804, 1808). Such construction can provide lower per-unit area resistance, relative to the VB 415 of FIG. 18. Moreover, an FTV 1206 may be cross sectionally larger than the VB 415 (e.g., may not correspond to a source/drain region 408 on a one-to-one basis, as some VB 415 may, as depicted in FIGS. 13-14), as may further decrease resistance. The FTV 1206 can include a metal via structure 1902 coupled between an MD structure or other portion of a front side metallization layer 108 and the backside metallization layer 112 without an intermediate semiconductive or silicide portion. As for the VD depicted in FIG. 18, the metal via structure 1902 or other components of the FTV 1206 (e.g., an MD, VD, VDR, etc.) can extend through a SiN or other intervening barrier layers 1810. The FTV 1206 can couple with or include a conductive line of a backside power rail 114, in some embodiments.

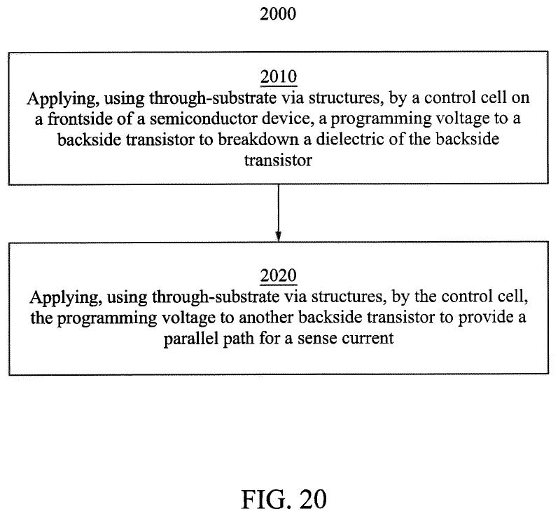

FIG. 20 illustrates a flow diagram for a method 2000 of data encoding, in accordance with some embodiments. Some operations may only be described briefly herein. However, one skilled in the art will understand that the disclosed operations may be performed in conjunction with other disclosed methods disclosed herein, or generally known in the art. Further, the order of the disclosed operations is not intended to be limiting. Certain operations may be performed in a different sequence, and still further operations may be sequenced with appropriate modifications thereto. The operations provided herein are not intended to limit the present disclosure. For example, operations or suboperations can be added, substituted, omitted, or otherwise modified.

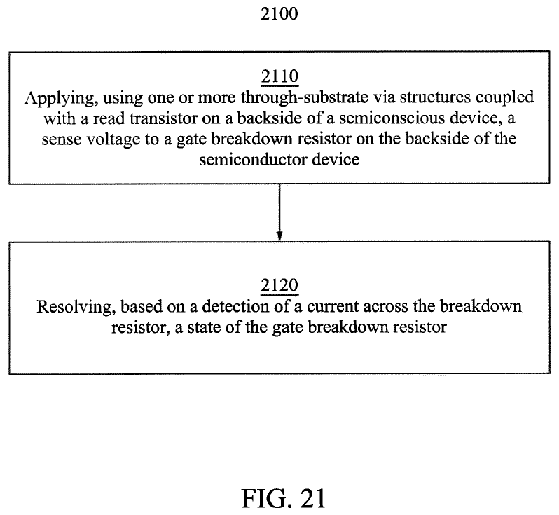

At operation 2010, the method 2000 includes applying a programming voltage to a backside transistor to breakdown a dielectric of the backside transistor. The programming voltage can be applied using through-substrate via structures, by an anti-fuse control cell on a frontside of a semiconductor device 100 (e.g., a WLP line 202). The anti-fuse control cell is further configured to sense a state of the dielectric of the first transistor. For exmaple, the anti-fuse control cell can be configured to actuate one or more read transistors (e.g., by actuating one or more WLR lines 204) to cause a sense current to flow to a bit line 206, as may be detected at the control cell, as is further described herein, according to the method 2100 of FIG. 21 and otherwise. In some embodiments, the through-substrate via structures include a feed-thorough via structure (FTV) 1206 laterally spaced from any transistors of the anti-fuse control cell, as may omit a semiconductive portion 1806 or a silicide junction 1804, 1808. In some embodiments, the through-substrate via structures include a backside via structure (VB) 415 inclduing a semiconductive portion 1806 coupled with a metal portion by a silicide junction 1804, 1808.

At operation 2020, the method 2000 includes applying the programming voltage to another backside transistor to provide a parallel path for a sense current. For example, the programming voltage can be applied using through-substrate via structures, by the anti-fuse control cell on a frontside of a semiconductor device 100 (e.g., the same or different through-substrate via structures, relative to operation 2010). In some embodiments, operation 2020 may be omitted, or the programming voltage can be applied to further transistors, as may provide additional parallel paths to reduce a bulk resistance of a breakdown resistor 301 formed from any number of transistors (e.g., IGZO transistors).

FIG. 21 illustrates a flow diagram for a method 2100 of accessing one-time programmable data, in accordance with some embodiments. Some operations may only be described briefly herein. However, one skilled in the art will understand that the disclosed operations may be performed in conjunction with other disclosed methods disclosed herein, or generally known in the art. Further, the order of the disclosed operations is not intended to be limiting. Certain operations may be performed in a different sequence, and still further operations may be sequenced with appropriate modifications thereto. The operations provided herein are not intended to limit the present disclosure. For example, operations or suboperations can be added, substituted, omitted, or otherwise modified.

At operation 2110, the method 2100 includes applying a sense voltage to a gate breakdown resistor 301 on the backside of a semiconductor device 100. For example, the sense voltage can be applied using one or more through-substrate via structures coupled with a read transistor on a backside of a semiconductor device 100. The sense voltage can refer to a voltage to complete a conduction channel 816 between source/drain region 818 of a transistor having a gate coupled with a WLR line 204, or a voltage applied across the breakdown resistor 301, as may be returned via a bit line 206. The gate breakdown resistor 301 can include a first broken down gate junction (e.g., gate oxide 804), and can further include further parallel broken down gate junctions. The one or more broken down gate junctions can be of a first transitror type, with a read transistor (e.g., having a gate coupled with the WLR line 204) of a different type. For exmaple, the different types can have different breakdown voltages, such that the read transitor transistor exhibits a higher breakdown voltage or a higher read current. The transistors (e.g., of the first or second type) can include indium gallium zinc oxide (IGZO) channels.

At operation 2120, the method 2100 includes resolving, based on a detection of a current across the breakdown resistor, a state of the gate breakdown resistor 301. An anti-fuse control cell is further configured to sense a state of the dielectric of the first transistor (e.g., according to a returned bitline 206 current). For exmaple, resolving the current can include comparing the current to one or more thresholds to determine if the state of the gate breakdown resistor is indicative of a logical zero, or a logical one. For exmaple, the resolution can include resolving against a first threhsold to determine a logical one and a second threshold to determine a logical zero. Values between the first threhsold and the second threhshold can refer to an undefined state. In some embodiments, the method 2100 includes comparisons to further thresholds, as in the case of a multi-bit bit cell.

Another method refers to another method of fabricating a semiconductor device. The method includes forming, on a front side of a substrate, a plurality of front side transistors. The method includes forming, on the front side of the substrate, a frontside metallization layer comprising a plurality of first conductive interconnects between the plurality of front side transistors. The method includes forming a plurality of through-substrate interconnects between the front side and a back side of the substrate. The method includes forming a plurality of backside transistors on the back side of the substrate; and applying a programming voltage configured to break down a dielectric of one or more of the plurality of backside transistors to form one or more gate breakdown resistors.

In some embodiments, the frontside metallization layer further comprises a plurality of second conductive interconnects between the front side transistors and the through-substrate interconnects.

In some embodiments, the method includes grinding the substrate to reduce a thickness prior to forming the plurality of backside transistors.

In some embodiments, at least a portion of the plurality of through-substrate interconnects are formed laterally offset from the plurality of front side transistors.

In some embodiments, at least a portion of the plurality of through-substrate interconnects are formed laterally under a source/drain region of the one or more of the plurality of front side transistors.

In some embodiments, the plurality of through-substrate interconnects comprise an epitaxial structure coupled with metal interconnects via silicide regions.

In some embodiments, the plurality of backside transistors comprise: a first set of transistors having a gate coupled with a first one or more of the through-substrate interconnects configured to carry the programming voltage, the programming voltage configured to break down the dielectric to form the one or more gate breakdown resistors; and a second set of transistors having a gate coupled with a second one or more of the through-substrate interconnects configured to carry a sensing voltage, the sensing voltage configured to drive a current across the gate breakdown resistor which is indicative of a state of the gate breakdown resistor.

In some embodiments, the plurality of backside transistors comprise a third set of transistors having a gate coupled with a third one or more of the through-substrate interconnects, wherein the first and third ones of the one or more of the through-substrate interconnects are parallel to one another.

In some embodiments, the first set of transistors are of a first type and the second set of transistors are of a second type, different from the first type, wherein the first type has a lower breakdown voltage than the second type and the second type has a greater read current than the first type.

In some embodiments, the plurality of backside transistors comprise: a third set of transistors of the first type, the third set of transistors having a gate coupled with a third one or more of the through-substrate interconnects, wherein the first and third ones of the one or more of the through-substrate interconnects are parallel to one another.

In one aspect of the present disclosure, a semiconductor device is provided. The semiconductor device includes an active region on a frontside of the semiconductor device. The active region includes an anti-fuse control cell including a plurality of first transistors. The semiconductor device includes a frontside metallization layer coupled with the plurality of first transistors. The semiconductor device includes a one-time-programmable circuit on a backside of the semiconductor device. The one-time-programmable circuit includes a second transistor coupled with a programing wordline (WLP) line of the anti-fuse control cell. The one-time-programmable circuit includes a third transistor coupled with a read wordline (WLR) line of the anti-fuse control cell. The semiconductor device includes a backside metallization layer coupled with the second and third transistor.

In another aspect of the present disclosure, a method of data encoding is provided. The method includes applying, using one or more through-substrate via structures, by an anti-fuse control cell on a frontside of a semiconductor device, a programming voltage to a first transistor on a backside of the semiconductor device to breakdown a dielectric of the first transistor. The anti-fuse control cell is further configured to sense a state of the dielectric of the first transistor.

In another aspect of the present disclosure, a method of accessing one-time programmable data is provided. The method includes applying, using one or more through-substrate via structures coupled with a read transistor on a backside of a semiconductor device, by an anti-fuse control cell on a frontside of the semiconductor device, a sense voltage to a gate breakdown resistor on the backside of the semiconductor device. The method includes resolving, based on a detection of a current across the gate breakdown resistor, a state of the gate breakdown resistor.

As used herein, the terms “about” and “approximately” generally indicates the value of a given quantity that can vary based on a particular technology node associated with the subject semiconductor device 100. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
an active region on a frontside of the semiconductor device, comprising:
an anti-fuse control cell comprising a plurality of first transistors; and
a frontside metallization layer coupled with the plurality of first transistors; and
a one-time-programmable circuit on a backside of the semiconductor device, comprising:
a second transistor coupled with a programing wordline (WLP) line of the anti-fuse control cell;
a third transistor coupled with a read wordline (WLR) line of the anti-fuse control cell; and
a backside metallization layer coupled with the second and third transistor.

2. The semiconductor device of claim 1, wherein a dielectric of the second transistor is broken down to form a gate breakdown resistor.

3. The semiconductor device of claim 2, further comprising a fourth transistor coupled with:
the second transistor at a first source/drain;
a bit line coupled with the third transistor at a second source/drain; and
the WLP line at a gate structure.

4. The semiconductor device of claim 1, wherein the plurality of first transistors comprise a through-substrate via structure from a source/drain to the backside metallization layer.

5. The semiconductor device of claim 4, wherein the through-substrate via structure comprises an epitaxial region coupled to metal regions via a silicide junction.

6. The semiconductor device of claim 1, further comprising an inactive region comprising:
a plurality of tap structures comprising parallel through-substrate via structures to couple the WLR line with the second transistor.

7. The semiconductor device of claim 1, further comprising a metal feed-through via structure laterally spaced from the plurality of first transistors to couple the WLR line with the second transistor.

8. The semiconductor device of claim 1, wherein the second transistor is of a first type, and the third transistor is of a second type, different from the first type.

9. The semiconductor device of claim 8, wherein the first type has a lower breakdown voltage than the second type and the second type has a greater read current than the first type.

10. The semiconductor device of claim 1, wherein the plurality of first transistors comprise a gate all around nanosheet transistor.

11. The semiconductor device of claim 1, wherein the active region on the frontside of the semiconductor device laterally overlaps with the one-time-programmable circuit on the backside of the semiconductor device.

12. A method of fabricating a semiconductor device, comprising:
forming, on a front side of a substrate, a plurality of front side transistors;
forming, on the front side of the substrate, a frontside metallization layer comprising a plurality of first conductive interconnects between the plurality of front side transistors;
forming a plurality of through-substrate interconnects between the front side and a back side of the substrate;
forming a plurality of backside transistors on the back side of the substrate; and
coupling the plurality of backside transistors with a voltage generator configured to apply a programming voltage to break down a dielectric of the plurality of backside transistors to form one or more gate breakdown resistors.

13. The method of claim 12, wherein the frontside metallization layer further comprises:
a plurality of second conductive interconnects between the plurality of front side transistors and the plurality of through-substrate interconnects.

14. The method of claim 12, wherein at least a portion of the plurality of through-substrate interconnects are formed laterally offset from the plurality of front side transistors.

15. The method of claim 12, wherein at least a portion of the plurality of through-substrate interconnects is formed laterally under a source/drain region of the one or more of the plurality of front side transistors.

16. The method of claim 12, wherein the plurality of through-substrate interconnects comprise an epitaxial structure coupled with metal interconnects via silicide regions.

17. The method of claim 12, wherein the plurality of backside transistors comprise:
a first set of transistors having a gate coupled with a first one or more of the plurality of through-substrate interconnects configured to carry the programming voltage, the programming voltage configured to break down the dielectric to form the one or more gate breakdown resistors; and
a second set of transistors having a gate coupled with a second one or more of the plurality of through-substrate interconnects configured to carry a sensing voltage, the sensing voltage configured to drive a current across the gate breakdown resistor which is indicative of a state of the gate breakdown resistor.

18. The method of claim 17, wherein:
the first set of transistors are of a first type and the second set of transistors are of a second type, different from the first type, wherein the first type has a lower breakdown voltage than the second type and the second type has a greater read current than the first type; and
the plurality of backside transistors comprise a third set of transistors of the first type, the third set of transistors having a gate coupled with a third one or more of the plurality of through-substrate interconnects, wherein the first one and the third one of the one or more of the plurality of through-substrate interconnects are parallel to one another.

19. A semiconductor device, comprising:
a first transistor on a backside of the semiconductor device;
a voltage generator configured to generate a programming voltage to breakdown a dielectric of the first transistor; and
an anti-fuse control cell on a frontside of the semiconductor device, coupled with the first transistor by one or more through-substrate via structures and configured to sense a state of the dielectric of the first transistor.

20. The semiconductor device of claim 19, further comprising:
second and third transistors on the backside of the semiconductor device, configured to provide parallel paths for a sense current used by the anti-fuse control cell to sense the state of the dielectric of the first transistor.
